(19) United States
(12) Patent Application Publication
(10) Pub. No.: US 2014/0176683 A1
(43) Pub. Date: Jun. 26, 2014

(54) IMAGING APPARATUS AND METHOD FOR CONTROLLING SAME

(71) Applicant: Kenji Miwa, Kawasaki-shi (JP)

(72) Inventor: Kenji Miwa, Kawasaki-shi (JP)

(73) Assignee: CANON KABUSHIKI KAISHA, Tokyo (JP)

(21) Appl. No.: 14/240,449

(22) PCT Filed: Sep. 6, 2012
(86) PCT No.: PCT/JP2012/005670

§ 371 Date: Feb. 24, 2014

(30) Foreign Application Priority Data
Sep. 13, 2011 (JP) 2011-199068

(51) Int. Cl. H04N 13/00; H04N 5/378

(52) U.S. Cl. CPC H04N 13/0007; H04N 5/378
USPC 348/49

(57) ABSTRACT

Provided is an imaging apparatus that includes a plurality of imaging elements having a plurality of PDs, where each of the plurality of PDs photoelectrically converts a light flux having passed through a different region of an exit pupil of an imaging optical system and output a left-eye image/right-eye image. The imaging apparatus generates a composite image based on the left-eye image and the right-eye image, calculates a positional shift amount of the left-eye image relative to a position of the composite image as a parallax amount, and stores information regarding the parallax amount as a parallax map. The imaging apparatus generates a left-eye image and a right-eye image to be reproduced by shifting an object included in the composite image to a position corresponding to the parallax amount indicated by the parallax map.

### TECHNICAL FIELD

The present invention relates to an imaging apparatus and a method for controlling the same.

### BACKGROUND ART

In recent years, there has been a rapid increase in the prevalence of devices associated with stereoscopic images such as three-dimensional (3D) cinema, 3D display, or the like. Conventionally, photographing stereoscopic images has been carried out by film cameras or the like. However, with the prevalence of digital imaging apparatuses, photographing original images for generating stereoscopic images using digital cameras, digital video cameras, or the like has become common.

As a mechanism by which a user views a stereoscopic image, data for a right-eye image and a left-eye image with parallax in the left right direction is prepared so as to correspond to an image of the object viewed with the left eye and an image of the object viewed with the right eye. A user can view stereoscopic images by viewing the right-eye image and the left-eye image with his/her right eye and left eye, respectively. Examples of such a method include a method for dividing a parallax image to be viewed, such as a parallax barrier method, a lenticular method, or the like. Also, a method for providing different images to the left eye and the right eye of a user via a filter having different characteristics between the left and right sides thereof is known.

On the other hand, as a method for capturing an image which is viewable as a stereoscopic image, Patent Literatures 1 and 2 disclose methods for simultaneously capturing images at different viewpoints. Patent Literature 1 discloses a solid-state imaging element in which a plurality of micro lenses is formed and at least one pair of photodiodes is arranged close to each of the micro lenses. Of the pair of photodiodes, a first image signal is obtained from the output of one photodiode and a second image signal is obtained from the output of the other photodiode. A user can view a stereoscopic image using the first and second image signals as a left-eye image and a right-eye image, respectively.

Also, Patent Literature 2 discloses an output parallax map having an output element which has an output value corresponding to a shift to be applied to each pixel of a first image. A second image can be generated based on the output parallax map and the first image.

### CITATION LIST

### Patent Literature

[Patent Literature 1]Japanese Patent Laid-Open No. 58-24105
[Patent Literature 2]Japanese Patent Laid-Open No. 2008-518317

In order to view a stereoscopic image, images with parallax in the left right direction need to be viewed by the corresponding eyes as described in the background art. Thus, in any one of technologies described in the background art, a “left eye image” for viewing by the left eye of a user and a “right-eye image” for viewing by the right eye thereof need to be prepared.

However, when photographing is performed using the solid-state imaging element disclosed in Patent Literature 1 in which a plurality of micro lenses is formed and at least one pair of photodiodes is arranged close to each of the micro lenses, the following problems may occur. Assume that one of a pair of photodiodes outputs a left-eye image which is obtained by photoelectrically converting a light flux having passed through a region of an exit pupil of an imaging optical system and the other outputs a right-eye image which is obtained by photoelectrically converting a light flux having passed through a region different from the region of the exit pupil. In this case, depending on the type of an object, neither the left-eye image nor the right-eye image may be an image reflecting the shape of the object.

For example, in a photographic scene in which light from a point light source is photographed in a blurred manner, a photograph of the light source blurred in a circular pattern should be taken originally. However, when an image is captured by the solid-state imaging element disclosed in Patent Literature 1, the captured image may be in a semicircular or elliptical shape not reflecting the shape of an object. In addition, for example, the shape of the object which is captured as an image is photographed in a different way between the left-eye image and the right-eye image such that the left half of the object in the left-eye image is missing and the right half of the object in the right-eye image is missing. The reason for this is that, among the light flux emitted from the exit pupil of the imaging optical system, the region of light received by a photodiode is different along the optical axis serving as the boundary.

Even when the imaging apparatus is adapted to generate a right-eye image based on a left-eye image and a parallax map by applying the technology disclosed in Patent Literature 2, the following problems still occur.

Specifically, the shape of the object in a left-eye image which is the basis of generation of a right-eye image is different from the shape of the actual object, and thus, a right-eye image correctly reflecting the shape of the object cannot be generated even it a parallax map is used.

### SUMMARY OF INVENTION

The imaging apparatus of the present invention includes an imaging element having a plurality of photoelectric conversion units configured to photoelectrically convert a light flux having passed through a different region of an exit pupil of an imaging optical system and output an image, and generates a right-eye image/left-eye image correctly reflecting the shape of an object based on the output image and the parallax amount.

According to an aspect of the present invention, an imaging apparatus is provided that includes an imaging element comprising a plurality of pixels each having a first photoelectric conversion unit configured to output a left-eye image by photoelectrically converting a light flux having passed through a region of an exit pupil of an imaging optical system and a second photoelectric conversion unit configured to output a right-eye image by photoelectrically converting a light flux having passed through a region different from the region of the exit pupil; a first image generation unit configured to generate a composite image by adding the left-eye image output by the first photoelectric conversion unit and the right-eye image output by the second photoelectric conversion unit for each pixel; a parallax calculation unit configured to calculate a positional shift amount of the left-eye image/right-eye image relative to a position of the generated composite image as a parallax amount and store the calculated parallax amount in a storage unit; and a second image generation unit configured to generate a left-eye image and a right-eye image to be reproduced by shifting an object included in the generated composite image to a position corresponding to the parallax amount stored in the storage unit.

Further features of the present invention will become apparent from the following description of exemplary embodiments with reference to the attached drawings.

### BRIEF DESCRIPTION OF DRAWINGS

FIG. 1 is a diagram schematically illustrating the general configuration of an imaging element according to an embodiment of the present invention.

FIG. 2A is a diagram illustrating the configuration of one pixel.

FIG. 2B is a diagram illustrating the arrangement of a pixel array 101.

FIG. 3 is a conceptual diagram illustrating how light fluxes emitted from the exit pupil of a photographing lens enter an imaging element.

FIG. 4 is a diagram illustrating an exemplary configuration of an imaging apparatus of the present embodiment.

FIGS. 5A to 5C are diagrams illustrating an example of parallax map generation processing according to a first embodiment.

FIG. 6 is a diagram schematically illustrating a parallax map.

### DESCRIPTION OF EMBODIMENTS

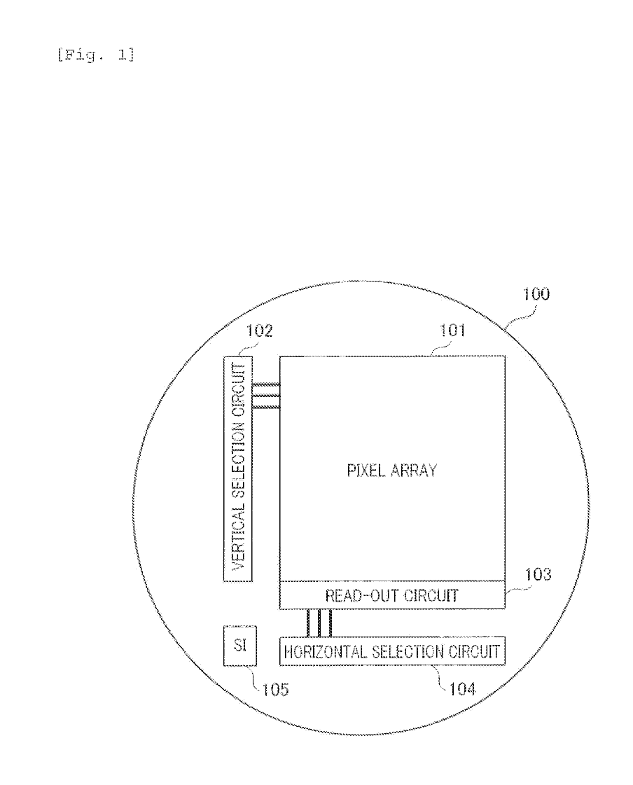

FIG. 1 is a diagram schematically illustrating an exemplary configuration of an imaging element that is applied to the imaging apparatus of the present embodiment. An imaging element 100 includes a pixel array 101, a vertical selection circuit 102 that selects a row in the pixel array 101, and a horizontal selection circuit 104 that selects a column in the pixel array 101. A read-out circuit 103 reads a signal of a pixel which has been selected from the pixels in the pixel array 101 by the vertical selection circuit 102. The read-out circuit 103 has a memory for accumulating signals, a gain amplifier, an AD converter, or the like for each column.

A serial interface (SI) unit 105 determines the operation mode of each circuit in accordance with the instructions given by an external circuit. The vertical selection circuit 102 sequentially selects a plurality of rows of the pixel array 101 so that a pixel signal(s) is extracted to the read-out circuit 103. Also, the horizontal selection circuit 104 sequentially selects a plurality of pixel signals read by the read-out circuit 103 for each row. Note that the imaging element 100 includes a timing generator that provides a timing signal to the vertical selection circuit 102, the horizontal selection circuit 104, the read-out circuit 103, and the like, a control circuit, and the like in addition to the components shown in FIG. 1, but no detailed description thereof will be given.

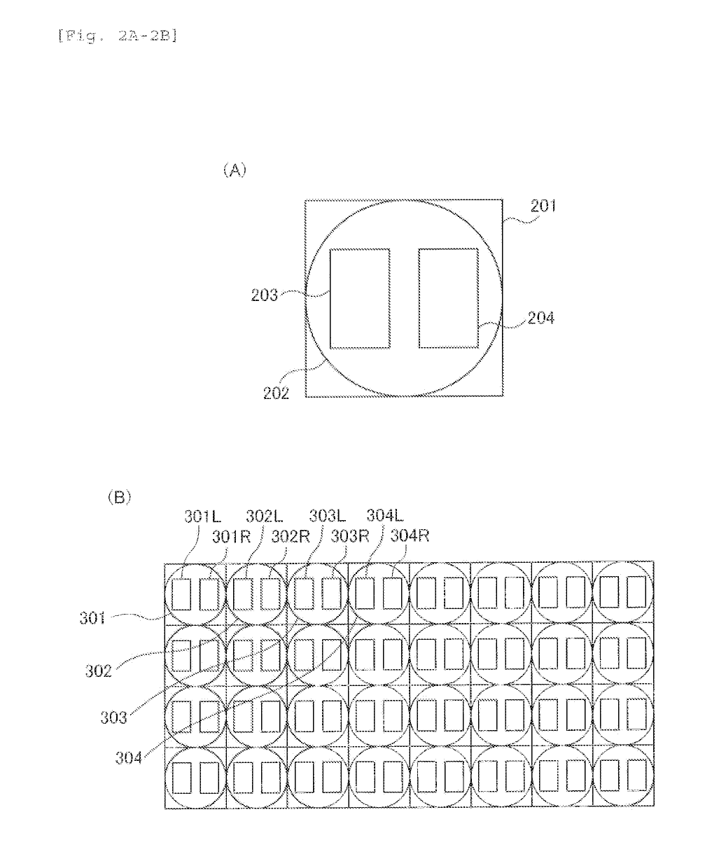

FIGS. 2A and 2B are diagrams illustrating an exemplary configuration of a pixel of the imaging element 100. FIG. 2A schematically shows the configuration of one pixel. FIG. 2B shows the arrangement of the pixel array 101. A pixel 201 shown in FIG. 2A has a micro lens 202 serving as an optical element and a plurality of photodiodes (hereinafter abbreviated as “PD”) serving as light receiving elements.

Although FIG. 2A shows an example in which a left-side PD 203 and a right-side PD 204 are provided for one pixel, three or more (e.g., four or nine) PDs may also be used. The PD 203 photoelectrically converts the received light flux to thereby output a left-eye image. The PD 204 photoelectrically converts the received light flux to thereby output a right-eye image. Note that the pixel 201 also includes a pixel amplifier for extracting a PD signal to the read-out circuit 103, a row selection switch, and a reset switch for resetting a PD signal in addition to the components shown in FIG. 2A.

In order to provide a two-dimensional image, the pixel array 101 is arranged in a two-dimensional array such as a plurality of pixels 301, 302, 303, and 304 as shown in FIG. 2B. Each of PDs 301L, 302L, 303L, and 304L corresponds to the PD 203 shown in FIG. 2A. Also, each of PDs 301R, 302R, 303R, and 304R corresponds to the PD 204 shown in FIG. 2A. In other words, the imaging apparatus of the present embodiment includes an imaging element including a plurality of pixels each having a first photoelectric conversion unit (the PD 203) configured to output a left-eye image and a second photoelectric conversion unit (the PD 204) configured to output a right-eye image.

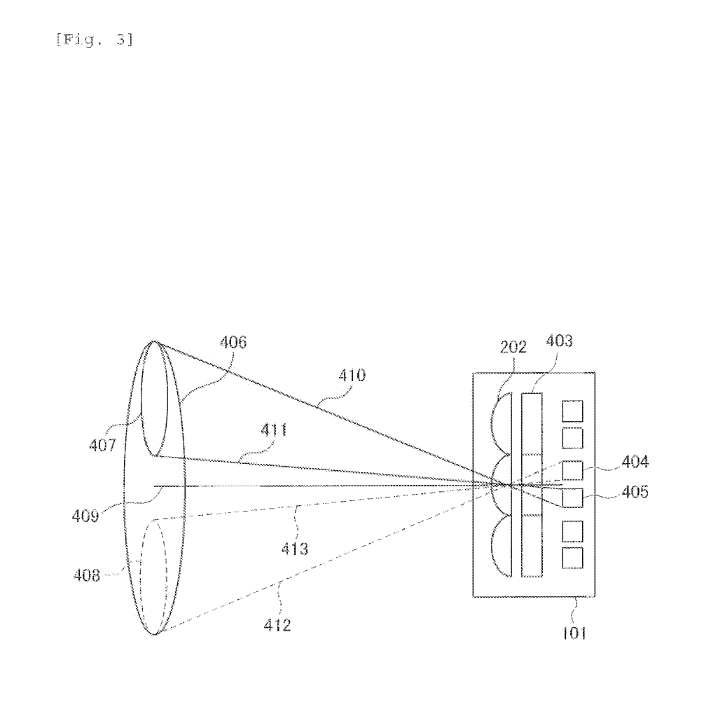

Next, a description will be given of the light receiving of the imaging element 100 having the pixel configuration shown in FIG. 2B. FIG. 3 is a conceptual diagram illustrating how light fluxes emitted from the exit pupil of a photographing lens enter the imaging element 100.

The pixel array 101 has a micro lens 202, a color filter 403, and PDs 404 and 405. The PDs 404 and 405 correspond to the PDs 203 and 204 shown in FIG. 2A, respectively.

In FIG. 3, the center axis of the light flux emitted from an exit pupil 406 of a photographing lens to the micro lens 202 is an optical axis 409. The light emitted from the exit pupil 406 enters the imaging element 100 about the optical axis 409. Each of the partial regions 407 and 408 is a region of the exit pupil 406 of the photographing lens. Light beams 410 and 411 are the outermost peripheral light beams of light passing through the partial region 407. Light beams 412 and 413 are the outermost peripheral light beams of light passing through the partial region 408.

Among the light fluxes emitted from the exit pupil 406, the upper light flux enters the PD 405 and the lower light flux enters the PD 404, with the optical axis 409 serving as the boundary. In other words, each of the PDs 404 and 405 receives a light flux emitted from a different region of the exit pupil of the photographing optical system. In this manner, each of the light receiving elements (PDs 404 and 405) detects light that has passed through a different region of the exit pupil. Thus, in the case where light from a point light source is photographed in a blurred manner, each of the light receiving elements obtains a photographic image with a different shape.

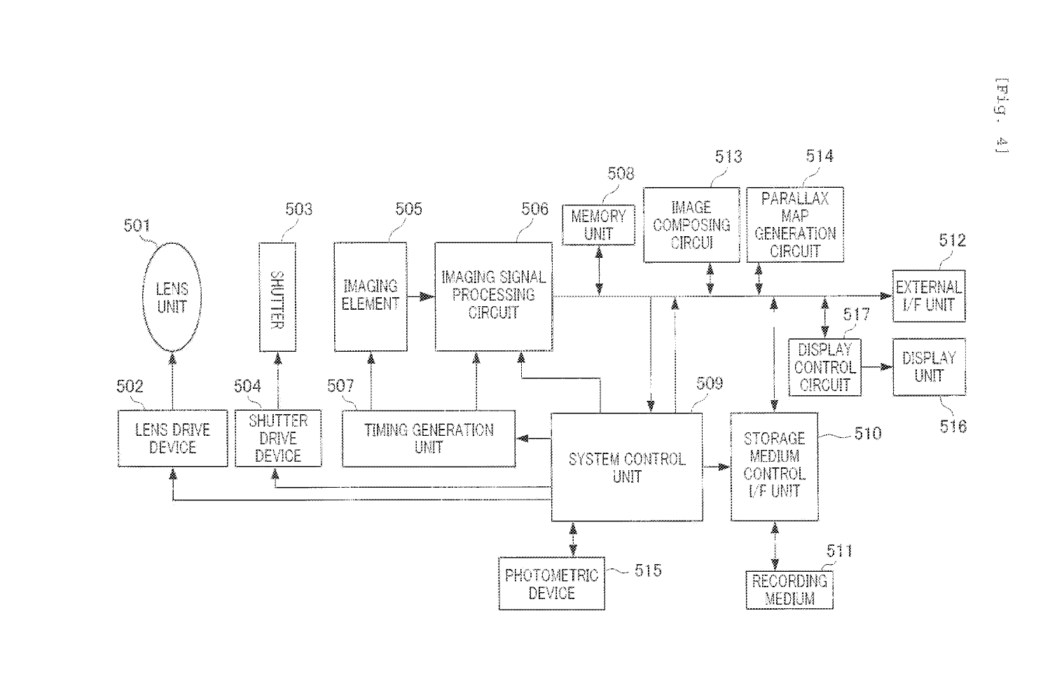

FIG. 4 is a diagram illustrating an exemplary configuration of an imaging apparatus of the present embodiment. With reference to FIG. 4, a description will be given of an exemplary application of the imaging element 100 shown in FIG. 1 to a digital camera serving as an imaging apparatus. A lens unit 501 constituting the imaging optical system focuses the light reflected from an object on an imaging element 505. The imaging element 505 corresponds to the imaging element 100 shown in FIG. 1 and has the pixel configuration shown in FIG. 2B.

A lens drive device 502 executes zoom control, focus control, diaphragm control, or the like. A mechanical shutter 503 is controlled by a shutter drive device 504. The imaging element 505 converts an object image focused by the lens unit 501 into an image signal. An imaging signal processing circuit 506 performs various kinds of processing or correction on the image signal output by the imaging element 505. A timing generation unit 507 outputs a timing signal required for the imaging element 505 or the imaging signal processing circuit 506.

A system control unit 509 is a control unit that performs various computations and controls the imaging apparatus overall. A CPU (Central Processing Unit) (not shown) provided therein executes a program to perform processing. As an operation specific to the present embodiment, the system control unit 509 generates a left-eye image and a right-eye image correctly reflecting the shape of an object based on the composite image generated by an image composing circuit 513 and the parallax map generated by a parallax map generation circuit 514. Also, the system control unit 509 reproduces the generated left-eye image and right-eye image, and a user can thereby view a stereoscopic image. Note that the system control unit 509 can also realize phase difference AF by detecting a phase difference between a left-eye image and a right-eye image.

A storage unit 508 includes a memory that temporarily stores image data. A storage medium control interface unit (hereinafter abbreviated as “I/F unit”) 510 is provided for recording/reading image data in/from a recording medium 511. The recording medium 511 which is detachable from the imaging apparatus is a semiconductor memory or the like. An external I/F unit 512 transmits/receives data to/from an external device. A display unit 516 displays various kinds of information or photographic images in accordance with display data from a display control circuit 517.

The imaging signal processing circuit 506 performs image processing by allocating imaging data output from the imaging element 505 to a left-eye image and a right-eye image. The memory unit 508 functions as a storage unit that stores the output data output from the imaging signal processing circuit 506, the composite image generated by an image composing circuit, and the parallax map generated by a parallax map generation circuit.

The image composing circuit 513 functions as a first image generation unit that composes a left-eye image with a right-eye image to thereby generate a composite image. The parallax map generation circuit 514 functions as a parallax calculation unit that executes the following processing. The parallax map generation circuit 534-calculates the positional shift amount between the left-eye image and the right-eye image on the basis of the position of the composite image as a parallax amount, and stores information regarding the calculated parallax amount as a parallax map in the memory unit 508. A photometric device 515 acquires a photometric value to be used for exposure control.

Next, a description will be given of the operation of a digital camera during imaging. When the main power supply is turned ON, the power supply of a control system circuit unit is turned ON and the power supply of an imaging processing system circuit such as the imaging signal processing circuit 506 is also turned ON. When a user operates a release button (not shown), the system control unit 509 computes in relation to focus state detection based on data from the imaging element 505 to thereby calculate the distance between the imaging apparatus and the object. Then, the lens drive device 502 drives the movable lens of the lens unit 501 and the system control unit 509 determines whether or not the focus state is in-focus.

When the system control unit 509 determines that the focus state is not in-focus, the system control unit 509 controls the drive of the lens unit 501 again to thereby execute focus state detection processing. For computation of the distance between the imaging apparatus and the object, besides a method for calculating the distance from data from the imaging element 505, a method for computing the distance using a distance measuring dedicated device (not shown) may also be used. The system control unit 509 starts the photographing operation after determination that the focus state is in-focus. When the photographing operation has been completed, the imaging signal processing circuit 506 processes the image signal output from the imaging element 505, and the system control unit 509 controls the writing of the image data to the memory unit 508.

Imaging data output from the imaging element 505 is output as image signals from a plurality of PDs. In the example shown in FIG. 2E, image signals are output in the order of the PDs 301L, 301R, 302L, 302R, 303L, 303R, 304L, and 304R. The imaging signal processing circuit 506 performs image processing by allocating imaging data output from the imaging element 505 to left-eye image data and right-eye image data. Left eye image data is image data obtained as a result of selecting and processing only the output from the left-side PDs 301L, 302L, 303L, and 304L shown in FIG. 2B. Also, right-eye image data is image data obtained as a result of selecting and processing only the output from the right-side PDs 301R, 302R, 303R, and 304R shown in FIG. 2B. Left eye image data and right-eye image data are separately held in the memory unit 508.

The image composing unit 513 reads left-eye image data and right-eye image data held in the memory unit 508 to thereby generate a composite image. The generated composite image data is stored in the memory unit 508. Image processing executed by the image composing unit 513 is processing for calculating an addition mean value for each pixel of a left-eye image and a right-eye image. Thus, the composite image generated by image processing has a shape reflecting the shape of an object. For example, if an object has a circular shape and both a left-eye image and a right-eye image have a semicircular shape, the composite image has the same circular shape as that of the object.

Even when an object is photographed with the imaging element 505 in a state where the shape of the object is different between a left-eye image and a right-eye image, the shape of the object image is interpolated by image processing performed by the image composing unit 513, resulting in the generation of image data in a correct shape. Note that the imaging signal processing circuit 506 may also be adapted to compose a left-eye image with a right-eye image both subjected to image processing.

Next, the parallax map generation circuit 514 generates a parallax map and stores the parallax map in the memory unit 508. The parallax map generation circuit 514 generates a parallax map by utilizing the positional shift amount between the left-eye image and the right-eye image on the basis of the position of the composite image as a parallax amount.

### First Embodiment

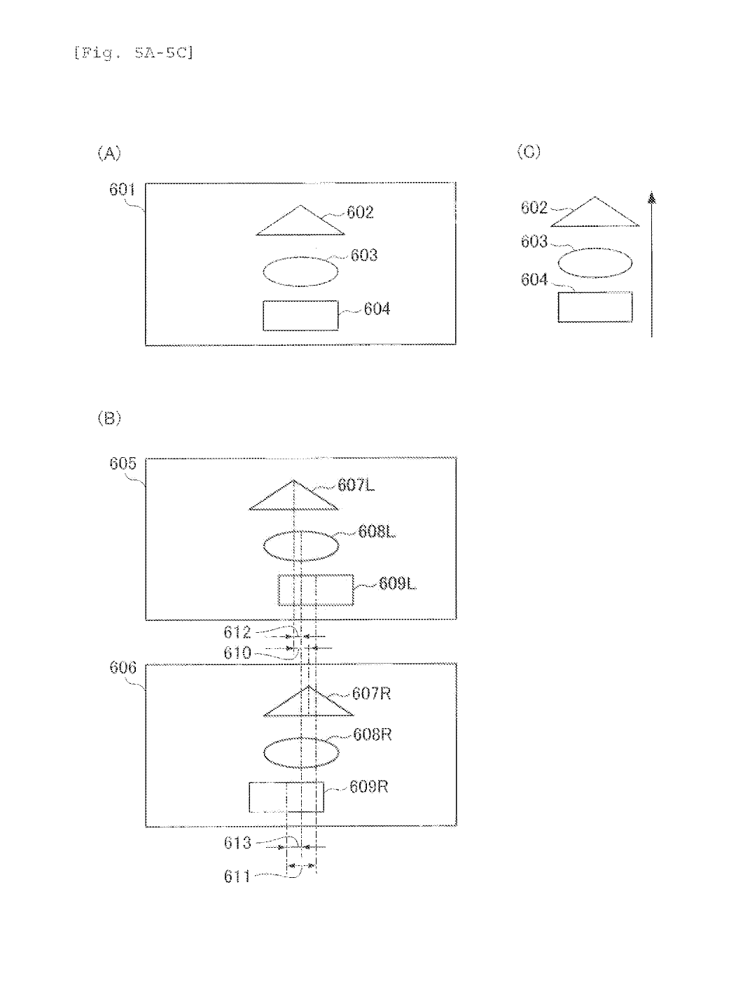

Hereinafter, a description will be given of a first embodiment. FIGS. 5A to 5C are diagrams illustrating an example of parallax map generation processing according to the first embodiment. Reference numeral 601 shown in FIG. 5A denotes the composition of the image obtained by photographing objects. Reference numerals 602, 603, and 604 denote objects. In the composition shown in FIG. 5A, the objects 602, 603, and 604 are arrayed in order from the top to the bottom. Also, as shown in FIG. 5C, the objects are arranged side by side in the depth direction. Reference numeral 604 denotes the closest object and reference numeral 602 denotes the furthest object.

FIG. 5B shows a stereo image obtained by photographing the composition shown in FIG. 5A. An image 605 is a left-eye image and an image 606 is a right-eye image. In the left-eye image 605, the objects 602, 603, and 604 are denoted as 607L, 608L, and 609L, respectively. In the right-eye image 606, the objects 602, 603, and 604 are denoted as 607R, 608R, and 609R, respectively.

There is a positional shift between an object in the left-eye image 605 and the object in the right-eye image 606. In the present embodiment, the amount of positional shift is defined as a parallax amount.

Reference numeral 610 denotes the amount of shift in position of the object 602 in the right-eye image 606 relative to the object 602 in the left-eye image 605 as a reference, i.e., a parallax amount between 607L and 607R. Likewise, reference numeral 611 denotes the amount of shift in position of the object 604 in the right-eye image 606 relative to the object 604 in the left-eye image 605 as a reference, i.e., a parallax amount between 609L and 609R. The position of the object 603 in the left-eye image 605 is the same as that in the right-eye image 606. In other words, there is no parallax amount for the object 603.

Firstly, the parallax map generation circuit 514 detects objects included in the left-eye image 605 and the right-eye image 606 using a known pattern matching method. The parallax map generation circuit 514 executes the following processing for each detected object. The parallax map generation circuit 514 calculates the positional shift amount between the midpoint which is located between the centroid of an object in the left-eye image 605 and that of the object in the right-eye image 606 and the centroid of the object in the left-eye image 605 as a parallax amount. In other words, the parallax map generation circuit 514 calculates the positional shift amount of the centroid of an object in the left-eye image relative to the position of the centroid of the object in the composite image generated on the basis of the left-eye image 605 and the right-eye image 606 as a parallax amount. The calculated parallax amount is a parallax amount corresponding to the left-eye image. Of course, the parallax map generation circuit 514 may also calculate the positional shift amount of the centroid of an object in the right-eye image relative to the position of the centroid of the object in the composite image as a parallax amount corresponding to the right-eye image.

In the example shown in FIG. 5B, for the object 602, the parallax map generation circuit 514 calculates a parallax amount 612, which is half of a parallax amount 610. For the object 604, the parallax map generation circuit 514-calculates a parallax amount 633, which is half of a parallax amount 611. The parallax map generation circuit 514 stores information regarding the calculated parallax amounts 612 and 613 and information about the position of an image serving as a reference for the parallax amount as a parallax map in the memory unit 508. In this example, information about the position of an image serving as a reference for the parallax amount indicates the centroid of an object in a composite image. As described above, in the example shown in FIG. 5B, there is no parallax amount for the object 603.

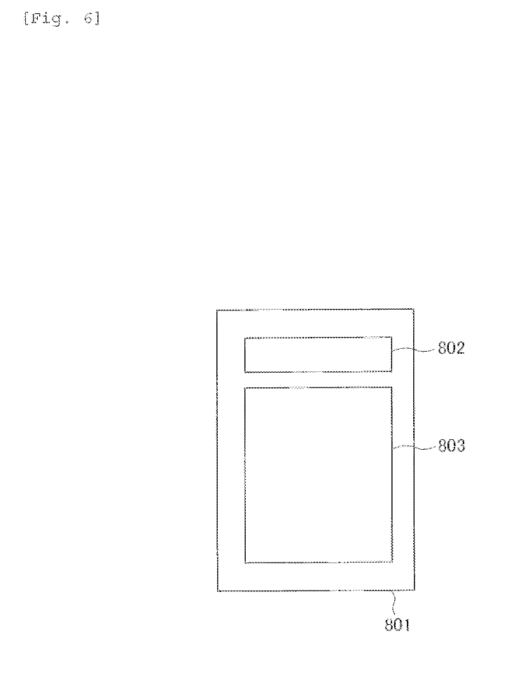

FIG. 6 is a diagram schematically illustrating a parallax map. A parallax map 801 includes a parallax amount 802 and information 803 about the position (the centroid) of an image serving as a reference for the parallax amount.

Next, a description will be given of image reproduction processing. The system control unit 509 functions as a second image generation unit that executes the following processing. The system control unit 509 reads a composite image and a parallax map from the memory unit 508. The system control unit 509 confirms that the position of an image serving as a reference for the parallax amount indicated by the parallax map is the centroid of an object in the composite image. Then, the system control unit 509 generates a left-eye image to be reproduced, that is, data for the reproduction of an image corresponding to the parallax amount, by shifting the object included in the composite image by the parallax amount indicated by the parallax map.

Also, the system control unit 509 inverts the parallax amount indicated by the parallax map. The system control unit 509 sets the parallax amount obtained by the inversion of the parallax amount indicated by the parallax map as the positional shift amount of the centroid of an object in the right-eye image relative to the centroid of the object in the composite image. Then, the system control unit 509 generates a right-eye image to be reproduced, that is, data for reproduction of an image other than the image corresponding to the parallax amount indicated by the parallax map, by shifting the object included in the composite image to the extent of the inversion of the parallax amount indicated by the parallax map.

By shifting an object in the composite image, a pixel at a position at which the object is arranged is a missing pixel. Thus, for example, the system control unit 509 imparts color space information to the missing pixel using a known technology disclosed in Japanese Patent No. 3524147. In other words, the system control unit 509 calculates an average of pixel values of pixels in the vicinity of the missing pixel as color space information, and imparts the calculated color space information to the missing pixel.

The imaging apparatus of the first embodiment composes a left-eye image with a right-eye image to thereby generate a composite image reflecting the shape of an object. The imaging apparatus generates information regarding the parallax amount on the basis of the position of the generated composite image as a parallax map. Then, the imaging apparatus generates a left-eye image and a right-eye image to be reproduced based on the composite image and the parallax amount indicated by the parallax map.

Thus, according to the imaging apparatus of the first embodiment, even if the shape of the left-eye image/right-eye image obtained by the photoelectrical conversion of a light flux having passed through a different region of an exit pupil of a photographing optical system is different from the shape of an object, an image correctly reflecting the shape of the object can be reproduced upon reproduction of the image. In other words, according to the imaging apparatus of the first embodiment, a right-eye image/left-eye image correctly reflecting the shape of an object can be generated based on the image output by photoelectrically converting a light flux having passed through a different region of an exit pupil of an imaging optical system and the parallax amount.

### Second Embodiment

Next, a description will be given of a second embodiment. The system control unit 509 provided in the imaging apparatus of the second embodiment calculates the positional shift amount of an image other than the image, which is either the left-eye image or the right-eye image at a position serving as a reference, as the parallax amount on the basis of the position of the left-eye image/right-eye image. The system control unit 509 stores the calculated parallax amount and information about the position of an image serving as a reference for the parallax amount as a parallax map in the memory unit 508. In this example, the position of a left-eye image is intended to be the position serving as a reference for the parallax amount.

In the example shown in FIG. 51, for the object 602, the parallax map generation circuit 514 calculates the positional shift amount of the centroid of an object in the right-eye image 606 relative to the centroid of the object in the left-eye image 605, i.e., the parallax amount 610. For the object 604, the parallax map generation circuit 514 calculates the positional shift amount of the centroid of an object in the right-eye image 606 relative to the centroid of the object in the left-eye image 605, i.e., the parallax amount 611.

The parallax map generation circuit 514 stores information regarding the calculated parallax amounts 610 and 611 and information about the position of an image serving as a reference for the parallax amount as a parallax map in the memory unit 508. In this example, information about the position of an image serving as a reference for the parallax amount indicates the centroid of an object in the left-eye image. Of course, the position of an image serving as a reference for the parallax amount may also be the centroid of an object in the right-eye image.

Next, a description will be given of image reproduction processing. The system control unit 509 reads a composite image and a parallax map from the memory unit 508. The system control unit 509 determines whether the parallax amount is a parallax amount on the basis of the position of a left-eye image or a right-eye image based on information about the position of an image serving as a reference for the parallax amount included in the parallax map. When the system control unit 509 determines that the parallax amount is based on the position of the left-eye image, the system control unit 509 sets the composite image as the left-eye image to be reproduced and generates a right eye image to be reproduced by shifting the object included in the composite image by the parallax amount. Also, when the system control unit 509 determines that the parallax amount is based on the position of the right-eye image, the system control unit 509 sets the composite image as the right-eye image to be reproduced and generates a left-eye image to be reproduced by shifting the object included in the composite image by the parallax amount.

In this example, the system control unit 509 determines that the position of an image serving as a reference for the parallax amount indicated by the parallax map is the centroid of an object in the left-eye image. Thus, the system control unit 509 sets the read composite image as a left-eye image to be reproduced. In the present embodiment, the left-eye image is an image other than the image corresponding to the parallax amount indicated by the parallax map. Also, the system control unit 509 generates a right-eye image to be reproduced, that is, data for reproduction of an image corresponding to the parallax amount, by shifting the object included in the composite image by the parallax amount indicated by the parallax map.

According to the imaging apparatus of the second embodiment, a composite image is used as it is as a left-eye image to be reproduced during image reproduction processing and a right-eye image to be reproduced can be generated by shifting the composite image by the parallax amount indicated by the parallax map. Thus, as compared with the first embodiment, the image processing amount required for reproduction of an image can be reduced, resulting in an increase in speed for the reproduction operation.

Aspects of the present invention can also be realized by a computer of a system or apparatus (or devices such as a CPU or MPU) that reads out and executes a program recorded on a memory device to perform the functions of the above-described embodiments, and by a method, the steps of which are performed by a computer of a system or apparatus by, for example, reading out and executing a program recorded on a memory device to perform the functions of the above-described embodiments. For this purpose, the program is provided to the computer for example via a network or from a recording medium of various types serving as the memory device (e.g., computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-199068 filed Sep. 13, 2011, which is hereby incorporated by reference herein in its entirety.

1. An imaging apparatus comprising:
an imaging element comprising a plurality of pixels each having a first photoelectric conversion unit configured to output a left-eye image by photoelectrically converting a light flux having passed through a region of an exit pupil of an imaging optical system and a second photoelectric conversion unit configured to output a right-eye image by photoelectrically converting a light flux having passed through a region different from the region of the exit pupil;
a first image generation unit configured to generate a composite image by adding the left-eye image output by the first photoelectric conversion unit and the right-eye image output by the second photoelectric conversion unit for each pixel;
a parallax calculation unit configured to calculate a positional shift amount of the left-eye image/right-eye image relative to a position of the generated composite image as a parallax amount and store the calculated parallax amount in a storage unit; and
a second image generation unit configured to generate a left-eye image and a right-eye image to be reproduced by shifting an object included in the generated composite image to a position corresponding to the parallax amount stored in the storage unit.

2. The imaging apparatus according to claim 1, wherein the second image generation unit generates data for reproduction of an image, which is either the left-eye image or the right-eye image corresponding to the parallax amount, by shifting the object included in the composite image by the parallax amount stored in the storage unit, and generates data for reproduction of an image other than the image, which is either the left-eye image or the right-eye image corresponding to the parallax amount, by shifting the object included in the composite image to the extent of the inverted parallax amount.

3. The imaging apparatus according to claim 1, wherein the parallax calculation unit calculates the positional shift amount of an image other than the image, which is either the left-eye image or the right-eye image at a position serving as a reference, as the parallax amount on the basis of the position of the left-eye image/right-eye image,
wherein the second image generation unit generates data for reproduction of an image, which is either the left-eye image or the right-eye image corresponding to the parallax amount, by shifting the object included in the composite image by the parallax amount stored in the storage unit, and sets the generated composite image as data for reproduction of an image other than the image which is either the left-eye image or the right-eye image corresponding to the parallax amount.

4. The imaging apparatus according to claim 3, wherein the parallax calculation unit stores the parallax amount and information about the position of an image serving as a reference for the parallax amount in the storage unit, and
wherein the second image generation unit determines whether the parallax amount stored in the storage unit is a parallax amount on the basis of the position of either the left-eye image or the right-eye image based on the information about the position of an image serving as a reference for the parallax amount stored in the storage unit,
wherein, when the second image generation unit determines that the parallax amount is a parallax amount on the basis of the position of the left-eye image, the second image generation unit sets the composite image as the left-eye image to be reproduced and generates data for reproduction of the right-eye image by shifting the object included in the composite image by the parallax amount, and
wherein, when the second image generation unit determines that the parallax amount is a parallax amount on the basis of the position of the right-eye image, the second image generation unit sets the composite image as the right-eye image to be reproduced and generates data for reproduction of the left-eye image by shifting the object included in the composite image by the parallax amount.

5. A method for controlling an imaging apparatus comprising an imaging element comprising a plurality of pixels each having a first photoelectric conversion unit configured to output a left-eye image by photoelectrically converting a light flux having passed through a region of an exit pupil of an imaging optical system and a second photoelectric conversion unit configured to output a right-eye image by photoelectrically converting a light flux having passed through a region different from the region of the exit pupil, the method comprising:
generating a composite image by adding the left-eye image output by the first photoelectric conversion unit and the right-eye image output by the second photoelectric conversion unit for each pixel;
calculating the positional shift amount of the left eye image/right-eye image relative to a position of the generated composite image as a parallax amount and storing the calculated parallax amount in a storage unit; and
generating a left-eye image and a right-eye image to be reproduced by shifting an object included in the generated composite image to a position corresponding to the parallax amount stored in the storage unit.
